(19) United States
(12) Patent Application Publication
(10) Pub. No.: US 2026/0353912 A1
(43) Pub. Date: Nov. 5, 2026

(54) LIGHT EMITTING ELEMENT, METHOD FOR MANUFACTURING LIGHT EMITTING ELEMENT, AND DISPLAY DEVICE

(71) Applicant: Sharp Display Technology Corporation, Kameyama City, Mie (JP)

(72) Inventors: Kota ADACHI, Sakai City, Osaka (JP); YASUSHI ASAOKA, Sakai City, Osaka (JP)

(21) Appl. No.: 19/486,514

(22) PCT Filed: May 16, 2024
(86) PCT No.: PCT/JP2024/018176

§ 371 Date: Nov. 21, 2025

(30) Foreign Application Priority Data
May 22, 2023 (WO) PCT/JP2023/018995

(51) Int. Cl. H10K 50/115; H10K 50/15; H10K 50/16; H10K 101/30; H10K 101/40

(52) U.S. Cl. CPC H10K 50/115; H10K 50/15; H10K 50/16; H10K 2101/30; H10K 2101/40

(57) ABSTRACT

A light-emitting element according to the present disclosure is structured such that a functional layer positioned between an anode and a cathode includes an emission layer, and such that the emission layer includes quantum dots and a matrix, includes an emission region in a portion where the anode and the cathode face each other, and is, in this region, divided by a gap extending from the front surface to back surface of the emission layer.

### TECHNICAL FIELD

The present disclosure relates to a light-emitting element, a method for manufacturing the light-emitting element, and a display device.

### BACKGROUND ART

In recent years, various display devices provided with light-emitting elements have been developed. Especially, display devices provided with quantum-dot light-emitting diodes (QLEDs) or organic light-emitting diodes (OLEDs) have attracted much attention because they can achieve low power consumption, thickness reduction, high image quality, and other advantages. Patent Literature 1 discloses OLEDs with improved light output.

### CITATION LIST

### Patent Literature

Patent Literature 1: International Publication No. 2008/140644

### SUMMARY

### Technical Problem

On the other hand, OLEDs, which contain inorganic materials as their emission materials, have a high refractive index and thus exhibit total reflection at the interfaces between their emission layers and transport layers, thereby degrading the efficiency of light extraction.

### Solution to Problem

To solve the aforementioned problem, a light-emitting element according to one aspect of the present disclosure includes a stack of an anode, a cathode, and a functional layer. The functional layer is positioned between the anode and the cathode. The emission layer includes quantum dots. The emission layer includes an emission region in a portion where the anode and the cathode face each other. The emission layer is divided by a gap extending from a front surface of the emission region to a back surface of the emission region.

A display device according to one aspect of the present disclosure includes a plurality of the light-emitting elements according to the aspect.

A method for manufacturing a light-emitting element according to one aspect of the present disclosure is a method for manufacturing the light-emitting element according to the aspect. The method includes the following steps: forming a coating layer including the quantum dots by coating any of the anode, the cathode, and the functional layer with a dispersion liquid in which the quantum dots are dispersed in a solvent, and by vaporizing the solvent through at least one of heating and depressurization; and forming the emission layer including the gap by further heating the coating layer after the step of forming the coating layer.

### Advantageous Effect of Disclosure

The aspects of the present disclosure can improve the efficiency of light extraction of a light-emitting element including quantum dots.

### BRIEF DESCRIPTION OF DRAWINGS

FIG. 1 is a plan view of the schematic configuration of a display device 100 according to one aspect of the present disclosure.

FIG. 2 is a plan view of the schematic configuration of light-emitting elements 1R, 1G, and 1B included in a plurality of light-emitting elements 1 provided in the display device 100 according to the aspect of the present disclosure.

FIG. 3 is a cross-sectional view of the schematic configuration of the light-emitting elements 1R, 1G, and 1B included in the light-emitting elements 1 according to the aspect of the present disclosure.

FIG. 4 is a schematic flowchart showing, by way of example, a first method for manufacturing each light-emitting element 1 included in a manufacturing method according to one aspect of the present disclosure.

FIG. 5 schematically illustrates a step of applying a quantum-dot dispersion liquid containing quantum dots 30L₁ and a precursor 31P; here, the step is included in the manufacturing method according to the aspect (first aspect) of the present disclosure.

FIG. 6 is a schematic diagram of a pre-heating layer obtained by coating the quantum-dot dispersion liquid containing the quantum dots 30L₁ and precursor 31P; here, the coating is included in the manufacturing method according to the aspect (first aspect) of the present disclosure.

FIG. 7 schematically illustrates a step of forming an emission layer 24; here, the step is included in the manufacturing method according to the aspect (first aspect) of the present disclosure.

FIG. 8 schematically illustrates a step of forming an electron transport layer 22; here, the step is included in the manufacturing method according to the aspect (first aspect) of the present disclosure.

FIG. 9 is a schematic diagram of the light-emitting element 1 including the emission layer 24; here the light-emitting element 1 is formed through the manufacturing method according to the aspect (first aspect) of the present disclosure.

FIG. 10 schematically illustrates a step of applying a quantum-dot dispersion liquid containing the quantum dots 30(L₂, L₃); here, the step is included in a manufacturing method according to one aspect (second aspect) of the present disclosure.

FIG. 11 is a schematic diagram of a pre-heating emission layer 24A obtained by coating the quantum-dot dispersion liquid containing the quantum dots 30(L₂, L₃); here, the coating is included in the manufacturing method according to the aspect (second aspect) of the present disclosure.

FIG. 12 is a schematic diagram of a light-emitting element 1A including the emission layer 24A; here the light-emitting element 1A is formed through the manufacturing method according to the aspect (second aspect) of the present disclosure.

FIG. 13 is a fluorescent-microscope image of the emission layer's surface in a light-emitting element according to Example 1 of the present disclosure.

FIG. 14 is a fluorescent-microscope image in Example 1 of the present disclosure.

FIG. 15 is a fluorescent-microscope image in Example 2 of the present disclosure.

FIG. 16 is a graph showing the correlation between current density and EQE in the examples of the present disclosure, in a comparison between a light-emitting element with a crack on the emission layer's surface and a light-emitting element without a crack on the emission layer's surface.

### DESCRIPTION OF EMBODIMENTS

### <Overview of Display Device>

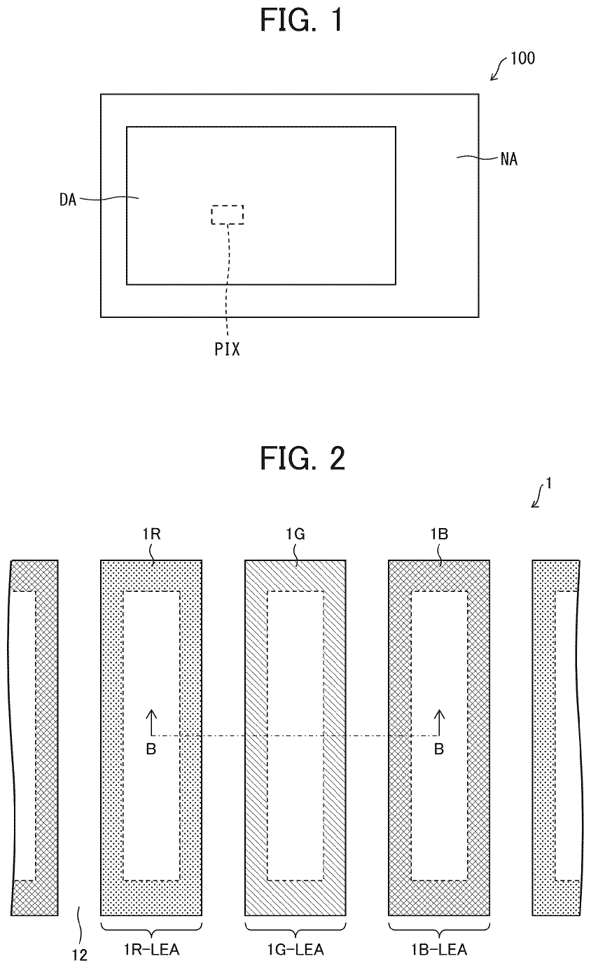

FIG. 1 is a plan view of an example schematic configuration of a display device 100 according to one aspect of the present disclosure. As illustrated in FIG. 1, the display device 100 according to the present disclosure includes a display region DA for performing display by extracting light from light-emitting elements, which will be described later on, and the display device 100 includes a frame region NA surrounding the perimeter of the display region DA. Although not shown, the frame region NA includes terminals to which a signal for driving the light-emitting elements of the display device 100 is input.

FIG. 2 is a plan view of an example schematic configuration of the display region DA illustrated in FIG. 1. FIG. 2 corresponds to an enlarged plan view of a single pixel PIX illustrated in FIG. 1. It is noted, as illustrated in FIG. 2, that light-emitting elements 1 include light-emitting elements 1R, 1G, and 1i, and that the light-emitting elements 1R, 1G, and 1B of the light-emitting elements 1 respectively include emission regions 1R-LEA (Light Emitting Area), 1G-LEA, and 1B-LEA surrounded by a bank 12 or a partition, which will be described later on. Each of these emission regions 1R-LEA, 1G-LEA, and 1B-LEA can constitute a subpixel within the single pixel PIX illustrated in FIG. 1.

### <Overview of Light-Emitting Elements>

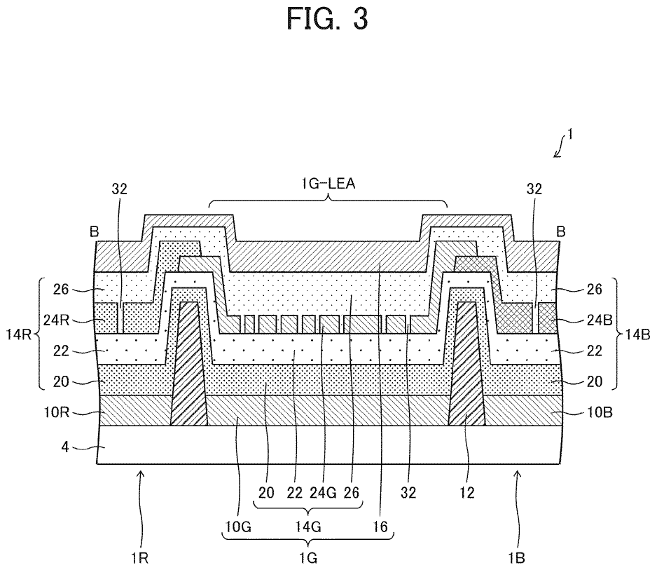

A first aspect of the configuration of the light-emitting elements 1 of the present disclosure will be described with reference, as appropriate, to the drawings. FIG. 3 is a cross-sectional view of the schematic configuration of the light-emitting elements 1 according to one aspect and corresponds to a cross-sectional view taken along line B-B in FIG. 2.

As illustrated in FIG. 3, the light-emitting elements 1R, 1G, and 1B according to the aspect include the following: a substrate 4; anodes 10R, 10G, and 10B formed on the substrate 4; a cathode 16; and functional layers 14R, 14G, and 14B provided between the anodes 10R, 10G, and 10B and the cathode 16. Here, the functional layers 14R, 14G, and 14B provided on the anodes 10R, 10G, and 10B each include the following: a hole injection layer (HIL) 20; a hole transport layer (HTL) 22; a corresponding one of emission layers (EML) 24R, 24G, and 24B; and an electron transport layer (ETL) 26. It can be expressed that in the light-emitting elements 1R, 1G, and 1i, the hole injection layer 20 and the hole transport layer 22 are provided between an anode 10 and the emission layer 24R, 24G, or 24B, and that in the light-emitting elements 1R, 1G, and 1i, the electron transport layer 26 is provided between the cathode 16 and the emission layer 24R, 24G, or 24B. It is noted that although FIG. 3 illustrates a light-emitting element having a known structure (known stacked structure) in which its anode is formed on the substrate, the light-emitting element may have an inverted structure (inverted stacked structure) in which its cathode, functional layer, and anode are formed in the stated order on its substrate.

As illustrated in FIGS. 1 and 2, the light-emitting elements 1R, 1G, and 1B are structured such that at least the respective anodes 10R, 10G, and 10B are separated from the emission layers 24R, 24G, and 24B by the bank 12. The light-emitting elements 1R, 1G, and 1B thus include their emission regions 1R-LEA, 1G-LEA, and 1G-LEA surrounded by the bank 12.

As illustrated in FIG. 3, the light-emitting element 1G, which emits green light, is formed inside an opening of the bank 12 provided on the substrate 4. The substrate 4 is, for instance, a substrate on which a barrier layer not shown, a thin-film transistor layer including a transistor TR, and the anode 10G are provided in the stated order from the substrate 4, and the substrate 4 can be an active matrix substrate. FIG. 3 mainly illustrates the light-emitting element 1G in cross-sectional view; the light-emitting elements 1R and 1B can have their configurations similar to that of the light-emitting element 1G.

The substrate 4 may be, for instance, a resin substrate made of a resin material, such as polyimide, or a glass substrate. For the display device 100 to be an inflexible display device, the substrate 4 can be a glass substrate.

The bank 12, which partitions the emission regions 1R-LEA, 1G-LEA, and 1G-LEA can be made of a resin material, such as polyimide or acrylic.

Each of the anodes 10R, 10G, and 10B is provided in the form of an island for each subpixel provided in the single pixel PIX illustrated in FIG. 1, and each anode is also referred to as a “pixel electrode”. The cathode 16 is also referred to as a “common electrode”.

Each of the anodes 10R, 10G, and 10B may be made of, for instance, an electrode material that reflects visible light, and the cathode 16 may be made of, for instance, an electrode material that transmits visible light.

The electrode material that reflects visible light may be any material that can reflect visible light and is conductive; examples include, but not limited to, metal materials, such as Al, Cu, Au, Mg, Li, and Ag, alloys of these metal materials, laminates of the metal material and a transparent metal oxide (e.g., an indium tin oxide, an indium zinc oxide, and an indium gallium zinc oxide), and laminates of the alloy and transparent metal oxide.

On the other hand, the electrode material that transmits visible light may be any material that can transmit visible light and is conductive; examples include, but not limited to, transparent metal oxides (e.g., an indium tin oxide, an indium zinc oxide, and an indium gallium zinc oxide), thin films made of a metal material, such as Al and Ag, and nanowires made of a metal material, such as Al and Ag.

The hole injection layer 20 can be a layer for injecting holes into the emission layers 24R, 24G, and 24B. The hole injection layer 20 is a layer that transports holes from each of the anodes 10R, 10G, and 10B to a corresponding one of the emission layers 24R, 24G, and 24B, and it can be one aspect of a hole transport layer. An example of the hole injection material contained in the hole injection layer is nanoparticles of, but not limited to, NiO, CuI, Cu₂O, CoO, Cr₂O₃, or CuAlS₂. The nanoparticles as the hole injection material may contain thiol or amine as their ligands.

The hole transport layer 22 is a layer that transports holes from each of the anodes 10R, 10G, and 10B to a corresponding one of the emission layers 24R, 24G, and 24B. The hole transport layer can be formed on the anodes or the hole injection layer.

The hole transport layer may be made of any hole transport material that can stabilize hole transport to the emission layers 24R, 24G, and 24B. The hole transport layer is preferably made of a hole transport material with high hole mobility. Furthermore, a preferable hole transport material is one that can avoid penetration of electrons moved from the cathode 16 (i.e., an electron-blocking material). This is because these hole transport materials can enhance the efficiency of hole-and-electron recombination within the emission layers 24R, 24G, and 24B. Examples of the hole transport material include, but not limited to, poly[N,N′-bis(4-butylphenyl)-N,N′-bis(phenyl)-benzidine](p-TPD), polyvinyl carbazole (PVK), and poly[(9,9-dioctylfluorenyl-2,7-diyl)-co-(4,4′-(N-4-sec-butylphenyl)) diphenylamine)](TFB). These hole transport materials may be used alone, or in combination of two or more kinds as appropriate. Other than the foregoing, a hole injection layer not shown may be formed. Examples include, but not limited to, a complex (PEDOT:PSS for short) of poly(3,4-ethylenedioxythiophene) (PEDOT) and polystyrene sulfonic acid (PSS), nickel oxide (NiO), and copper thiocyanate (CuSCN). It is noted that these materials may be used alone, or in combination of two or more kinds as appropriate.

The emission layers 24R, 24G, and 24B are layers that emit light upon recombination of a hole from the anode 10 and an electron from the cathode 16 to excite an emitter, which then goes back to aground state. An emission layer 24 includes an emission region 1-LEA in a portion where the anode 10 and the cathode 16 face each other; upon voltage or current application to the emission region 1-LEA, the emission layer 24 exhibits such recombination and thus emits light.

The emission layers 24R, 24G, and 24B can emit any of red light, green light, and blue light in the respective emission regions 1R-LEA, 1G-LEA, and 1B-LEA. Here, the red light is light having an emission center wavelength in a wavelength band ranging from 600 nm exclusive to 780 nm inclusive. Further, the green light is light having an emission center wavelength in a wavelength band ranging from 500 nm exclusive to 600 nm inclusive. Furthermore, the blue light is light having an emission center wavelength in a wavelength band ranging from 400 to 500 nm both inclusive. It is noted that although a plurality of kinds of quantum dots is combinations of a red quantum dot, green quantum dot, and blue quantum dot in one aspect, they do not necessarily have to be these combinations.

The emission layers 24R, 24G, and 24B in the respective emission regions 1R-LEA, 1G-LEA, and 1B-LEA include, as emitters, quantum dots including organic ligands. Here, the “quantum dots” are dots having a maximum width of 100 nm or less.

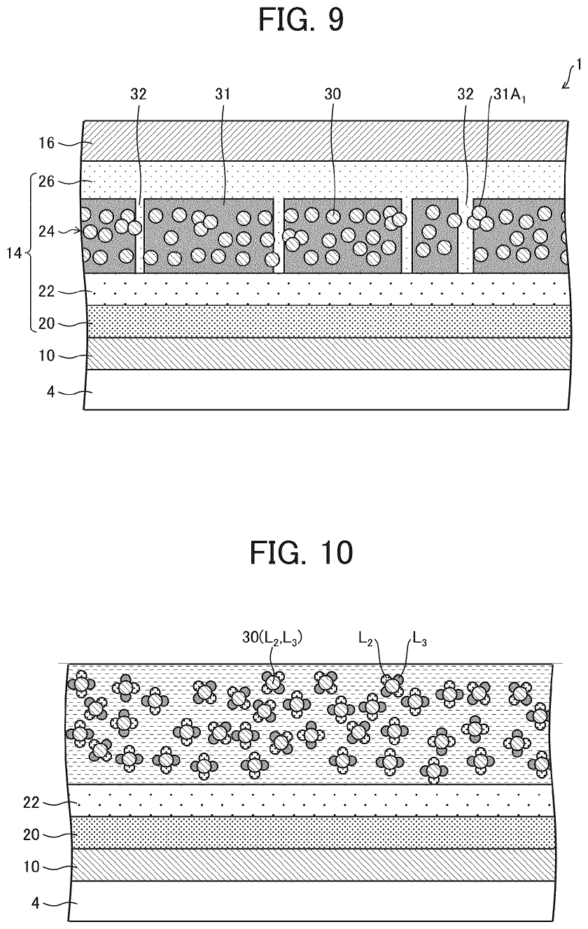

In the light-emitting element 1 according to one aspect (first aspect), the emission layer 24, including the emission layer 24R, 24G, or 24B, may include aggregates of quantum dots 30 in a matrix 31 of a metal sulfide, which will be described later on (FIG. 9). This metal sulfide matrix 31 may be formed from a precursor 31P of a metal sulfide, which will be described later on.

Further, in a light-emitting element 1A according to one aspect (second aspect), the emission layer 24A may include quantum dots 30L₂ including ligands L₂, or quantum dots 30L₃ including ligands L₃, both of which will be described later on (FIG. 12).

In the light-emitting element 1 according to one aspect (first modification), the emission layer 24, such as the emission layer 24R, 24G, or 24B, may include the quantum dots 30 in the matrix 31 of a silicon oxide (FIG. 9) instead of a metal sulfide. This silicon oxide matrix 31 may be formed from a ligand material, which will be described later on, and a medium material, which will be described later on and is the precursor 31P of a silicon oxide.

Further, in the light-emitting element 1A according to one aspect (second modification), the emission layer 24A may include the quantum dots 30(L₂, L₃) including, as will be described later on, a low-polarity ligand material as the ligands L₂, and a high-polarity ligand material as the ligand L₃.

The emission layers 24R, 24G, and 24B can be each a layer of a continuous film of an inorganic matrix represented by a metal sulfide including quantum dots and a silicon oxide including quantum dots, both of which will be described later on, and are each divided by a plurality of gaps 32 extending from the layer's front surface to back surface. Although how the gaps 32 divide the emission layer 24 is limiting, the gaps 32 can be formed as cracks dividing the individual emission layers 24R, 24G, and 24B randomly when viewed from the upper surface of the emission regions of these emission layers. It is noted that when the gaps 32 of the emission layers 24R, 24G, and 24B are provided as random cracks for instance, these random cracks may be provided in such a manner that at least some of them penetrate from the front surfaces through back surfaces of the emission layers. In other words, at least some of the random cracks may have a depth corresponding to the thicknesses of the emission layers 24R, 24G, and 24B.

The light emitting layers 24R, 24G, and 24B have improved efficiency of light extraction thanks to light scattering at the interface between the surfaces of the emission layers as well as the surfaces of the gaps 32 and the electron transport layer 26. This can enhance external quantum efficiency (EQE) in the emission layers 24R, 24G, and 24B. The occupancy rate of the gaps 32 that is suitable for the light scattering effect can be expressed as follows. That is, the area ratio occupied by the gaps 32 on the surfaces of the emission layers 24R, 24G, and 24B is preferably 5 to 10% both inclusive of the area. The occupancy rate of the gap 32 in each of the emission layers 24R, 24G, and 24B can be determined through image analysis. To be more specific, the gap 32 can be determined by subjecting image data obtained from a fluorescence micrograph of a corresponding one of the light-emitting elements to grayscale conversion into a binary representation to thus evaluate its occupancy rate.

Further, the width of the gaps 32 is preferably larger than the wavelength of light emitted from the quantum dots and preferably measures 2 μm or less. Here, the “width” of the gaps 32 may be determined by, for example, photographing randomly extending cracks on the surfaces of the corresponding emission layer, followed by subjecting the obtained photograph to grayscale conversion into a binary representation, followed by identifying the largest crack having a length satisfying a condition, i.e., at least 5 μm or more, from the binarized image data, and measuring the crack's maximum width.

In the emission layers 24R, 24G, and 24B, the degree of light scattering varies depending on the occupancy rate of the gaps 32; this can change the efficiency of light extraction in the emission layers. The efficiency of light extraction can be varied depending on the difference between the average refractive index of the emission layers provided with the gaps and the refractive index of the material of the emission layers, i.e., the refractive indexes of the emission layers provided with no gaps. Within a range of 0.1 to 1.0, the larger the difference between the average refractive index of the emission layers provided with the gaps and the refractive index of the material of the emission layers is, the higher the efficiency of light extraction in the emission layers can be achieved, and within the range of 0.1 to 1.0, the smaller the difference is, the larger the occupancy ratio of the gaps in the emission layers is; this can avoid degradation in the electrical property of the emission layers per se. Here, the average refractive index of the emission layers provided with the gaps and the refractive index of the material of the emission layers can be measured through ellipsometry or other methods.

The emission layers 24R, 24G, and 24B illustrated in FIG. 3 are individually structured such that an end of the emission layer 24R and an end of the emission layer 24G overlap on the bank 12, and such that an end of the emission layer 24G and an end of the emission layer 24B overlap on the bank 12. Further, although not shown, an end of the emission layer 24B and an end of the emission layer 24R may overlap. The overlaps of the ends of the emission layers 24R, 24G, and 24B can increase the thickness of the emission layers on the bank 12, so that current via the emission layers is less likely to flow on the bank 12. This can prevent unintended light emission on the bank 12.

It is preferable in the light-emitting elements 1 to reduce current, so-called leakage current, that flows directly through the anode and cathode via only the hole injection layer 20 and hole transport layer 22 of the functional layers 14R, 14G, and 14B, or via only the electron transport layer 26 of the functional layers 14R, 14G, and 14B. It is thus preferable that each gap 32 be filled with at least a layer being in contact with the upper surface of a corresponding one of the emission regions in which the gap 32 is provided; that is, the gap 32 be filled with at least a part of the electron transport layer 26. This structure can avoid leakage current in the gaps 32 between the cathode 16 and hole transport layer 22. Further, since the hole transport layer 22 and the electron transport layer 26 are in direct contact in the gaps 32, the gaps preferably have such a physical property as to avoid leakage current between both layers. To be specific, the difference between the HOMO level of the material of the hole transport layer 22 and the HOMO level of the material of the electron transport layer 26 stands at 1.0 eV or more, preferably at 1.5 eV or more, and more desirably at 2.0 eV or more; in addition, the difference between the LUMO level of the material of the hole transport layer 22 and the LUMO level of the material of the electron transport layer 26 stands at 1.0 eV or more, preferably at 1.5 eV or more, and more desirably at 2.0 eV or more.

The electron transport layer 26 transports electrons from the cathode 16 to the emission layers 24R, 24G, and 24B. It is noted that although not shown, this charge transport layer may be formed from a plurality of layers.

The electron transport material 26 may be made of any electron transport material that can stabilize electron transport to the emission layers 24R, 24G, and 24B. Examples of the electron transport material include ZnO nanoparticles, ZnS nanoparticles, ZrO nanoparticles, MgZnO nanoparticles, AlZnO nanoparticles, and TiO₂ nanoparticles. These nanoparticles may include ligands, such as organic ligands and inorganic ligands, on their surfaces.

### [Method for Manufacturing Light-Emitting Element According to First Aspect]

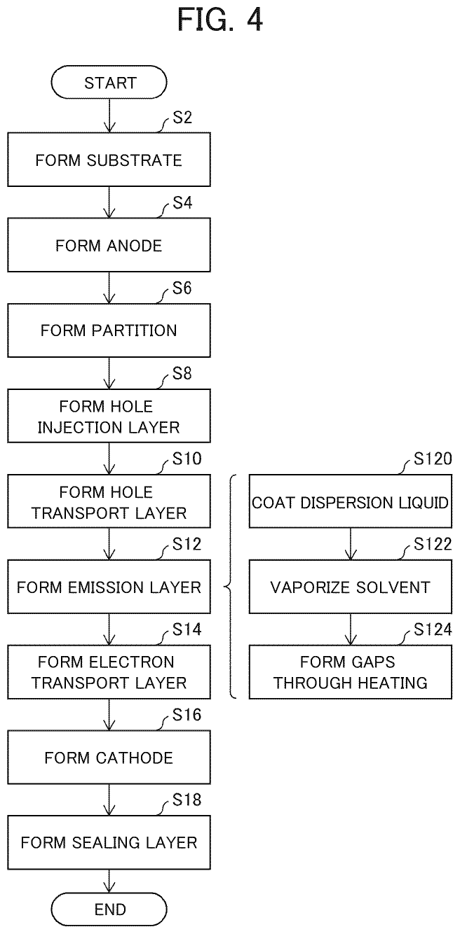

The light-emitting element 1 according to the first aspect can be offered by a first manufacturing method described below. FIG. 4 is a schematic flowchart showing the first method for manufacturing the light-emitting element 1 according to one aspect.

In the method for manufacturing the light-emitting element according to the aspect, the first process step is forming the substrate 4 (Step S2). The substrate 4 may be formed by forming TFTs directly onto a rigid glass substrate.

The next (Step S4) is forming an anode onto the substrate 4. The anode may be executed by, for instance, forming a thin film made of metal through a technique, including sputtering and vacuum evaporation, followed by patterning the thin film through dry etching or wet etching using a photoresist. Accordingly, the anode 10 (i.e., the anode 10R, the anode 10G, and the anode 10B) is formed in the form of an island on the substrate 4 for each subpixel constituting the single pixel PIX.

The next (Step S6) is forming the bank 12 that is insulating, to cover the edge of the anode 10. The bank 12 is made of a resin material, such as polyimide or acrylic, and can be formed in a desired pattern through photolithography.

The next (Step S8) is forming the hole injection layer 20. In the formation of the hole injection layer 20, an example method of forming the hole injection layer 20 is obtaining a dispersion liquid containing a hole transport material by dispersing a hole injection material in a solvent, followed by applying this hole-injection-material dispersion liquid onto the bank 12 and anode 10, followed by volatilization through heating or other methods to remove the solvent from the hole injection material.

The next (Step S10) is forming the hole transport layer 22. In the formation of the hole transport layer 22, an example method of forming the hole transport layer 22 is preparing a liquid containing a hole transport material by dissolving a hole transport material in a solvent, followed by applying this hole-transport-material liquid onto the hole injection layer 20, followed by volatilization through heating or other methods, to remove the solvent from the hole transport material.

It is noted that the hole injection layer 20 and the hole transport layer 22 may be formed without the foregoing patterning after the volatilization to remove their solvents. In this case, the manufacturing process does not become complicated, thus offering easy manufacturing. Further, the hole injection layer and hole transport layer on the bank between pixels may be formed as a plurality of discontinuous layers by patterning a hole-transport-material thin film through dry etching or wet etching using a photoresist.

The next (Step S12) is forming the emission layer 24. As illustrated in FIGS. 4 to 7, the method of forming the emission layer 24 includes the following: a step (S120) of coating the hole transport layer 22 with a quantum-dot-30L₁ dispersion liquid with quantum dots 30L₁ dispersed and with the metal sulfide precursor 31P dissolved; a step (S122) of forming a layer including the quantum dots 30L₁ by vaporizing the solvent through at least one of heating and depressurization; and a step (S124) of forming the emission layer 24 provided with the gap 32 by further heating the layer including the quantum dots 30L₁.

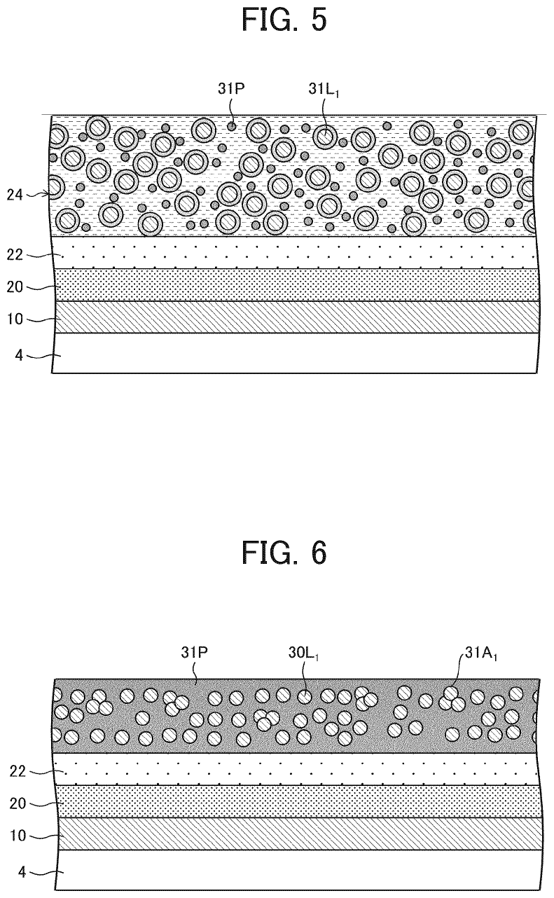

As earlier described, the “quantum dots” are dots having a maximum width of 100 nm or less. In the step (S120) of coating the hole transport layer 22 with the quantum-dot-30L₁ dispersion liquid illustrated in FIGS. 4 and 5, the quantum dots 30 with ligands L₁ coordinating therewith may have any shape satisfying this maximum width, such as a spherical tridimensional shape (circular cross-section shape), a polygonal cross-section shape, a bar-shaped tridimensional shape, a branch-shaped tridimensional shape, a tridimensional shape having surface asperities, or a combination thereof, in one aspect, a cubic shape is preferable.

The quantum dots 30 each may have, for instance a core structure, a core-shell structure, a core-shell-shell structure, or a core-shell structure with the ratio continuously varied. It is noted that the sell may cover the core completely or partly. In a mono-component system, the core portion can contain, for example, Si or C. In a binary system, the core portion can contain, for example, CdSe, CdS, CdTe, InP, GaP, InN, ZnSe, ZnS, or ZnTe. In a ternary system, the core portion can contain, for example, CdSeTe, GaInP, or ZnSeTe. In a quaternary system, the core portion can contain, for example, AgInGaS (AIGS). In the binary system, the shell portion can contain, for example, CdS, CdTe, CdSe, ZnS, ZnSe, or ZnTe. In the ternary system, the shell portion can contain, for example, CdSSe, CdTeSe, CdSTe, ZnSSe, ZnSTe, ZnTeSe, or AgInP (AIP).

In the quantum-dot-30L₁ dispersion liquid, each ligand L₁, which is an organic ligand, coordinating with the corresponding quantum dot 30 includes a coordinating group selected from the group consisting of an amino group, a mercapto group, a carboxylic acid group, and a phosphonate group, or includes a coordinating group selected from a dithiocarboxylic acid group, a xanthogenic acid group, and a thiourea group, and each ligand L₁ may include a hydrocarbon group having 1 to 5 carbon atoms, or a hydrocarbon group having 6 to 24 carbon atoms. In addition, the quantum dot 30 preferably includes a coordinating group selected from a dithiocarboxylic acid group, a xanthogenic acid group, and a thiourea group, as the coordinating group of the ligand L₁. This can incorporate the quantum dots 30 into the matrix 31, which derives from the ligands L₁ and precursor 31P. Here, although not restrictive, the organic ligands L₁ that are not a halogen (halogen ions) represented by chlorine by way of example are preferable from the viewpoint that such a ligand L₁ prevents a repulsion between the quantum dot 30L₁ and the precursor 31P, so that the gap 32 can be formed successfully, as will be described later on.

The concentration of the quantum dots 30L₁ contained in the quantum-dot-30L₁ dispersion liquid is a non-limiting value within a range of, for instance, 1.4 to 12.5 parts by mass with respect to the total of the quantum dots 30L₁ and solvent standing at 100 parts by mass. This can form the emission layer 24 incorporating the quantum dots 30 and produce the cracks by heating the emission layer 24.

The precursor 31P contained in the quantum-dot-30L₁ dispersion liquid is a metal complex; the precursor 31P preferably contains, for example, zinc (Zn), magnesium (Mg), or gallium (Ga) as the metal (metal ion) of the metal complexes, and the precursor 31P may further contain tellurium (Te); the metal is more desirably zinc (Zn). Further, the ligand of the metal complex, which is the precursor 31P, can be a ligand including the coordinating group, of the ligand L₁ included in the quantum dots 30, selected from the dithiocarboxylic acid group, xanthogenic acid group, and thiourea group, and including a hydrocarbon group having 1 to 24 carbon atoms.

The ligand of the metal complex, which is the precursor 31P, includes the coordinating group, of the ligand L₁, selected from the dithiocarboxylic acid group, xanthogenic acid group, and thiourea group, so that the matrix 31 of a metal sulfide can be formed from the ligands L₁ and precursor 31P. Further, the hydrocarbon group included in the ligands L₁ can enhance the contraction of the metal sulfide along with increase in the number of carbon atoms within a range of 1 to 24, so that the gaps 32, which are cracks, can be formed successfully. The hydrocarbon group included in the ligands L₁ can also lower pyrolysis temperature along with decrease in the number of carbon atoms within the range of 1 to 24. For instance, the hydrocarbon group included in the ligands L₁ preferably has 6 to 24 carbon atoms in view of easy crack formation, and it preferably has 1 to 5 carbon atoms from the viewpoint of lowering the pyrolysis temperature. The ligands L₁ are referred to as thermally decomposable ligands in some cases, because they are thermally decomposed by heat.

The concentration of the precursor 31P contained in the quantum-dot-30L₁ dispersion liquid is a non-limiting value within a range of, for instance, 40 to 100 parts by mass with respect to the quantum dots 30L₁ of 100 parts by mass. This can form the emission layer 24 and produce the cracks.

In the quantum-dot-30L₁ dispersion liquid, the solvent that disperses the quantum dots 30L₁ and dissolves the precursor 31P is preferably a non-polar solvent or a low-polarity solvent. An example of the non-polar solvent is, but not limited to, aromatic hydrocarbon solvents, such as toluene and xylene. Examples of the low-polarity solvent include, but not limited to, the following: halogenated aromatic hydrocarbon solvents, such as chlorotoluene, chlorobenzene, bromobenzene, and iodobenzene; halogenated aliphatic hydrocarbon solvents, such as chloroform and tetrachloromethane; and ether solvents, such as cyclopentylmethyl ether and dimethyl ether. The solvent that is a low-polarity solvent can disperse the quantum dots 30L₁ stably within the quantum-dot-30L₁ dispersion liquid and dissolve the precursor 31P within the quantum-dot-30L₁ dispersion liquid.

The coating of the quantum-dot-30L₁ dispersion liquid onto the hole transport layer 22 can be performed through a publicly known coating method, such as spin coating, slit coating, or inkjet printing.

In the step (S122) of forming the layer including the quantum dots 30L₁ shown in FIGS. 4 and 6, the solvent may be removed from the quantum-dot-30L₁ dispersion liquid coated on the hole transport layer 22 by either or both of heating and depressurization. This forms a coating layer including the quantum dots 30L₁ and agglomerates some of the quantum dots 30 within the coating layer, so that aggregates 30A₁ of the quantum dots can be formed. The condition of drying (preliminary-drying condition) the coating layer formed by applying the quantum-dot-30L₁ dispersion liquid is non-limiting, but the condition of heating the same may be any temperature lower than the decomposition temperature of the ligands L₁; the heating can be performed at 50 to 200 °C, and preferably at 130 °C or lower when isopropyl xanthate is used as the ligands L₁. This process step can be also referred to as a step of preliminarily drying the coating layer including the quantum dots 30L₁.

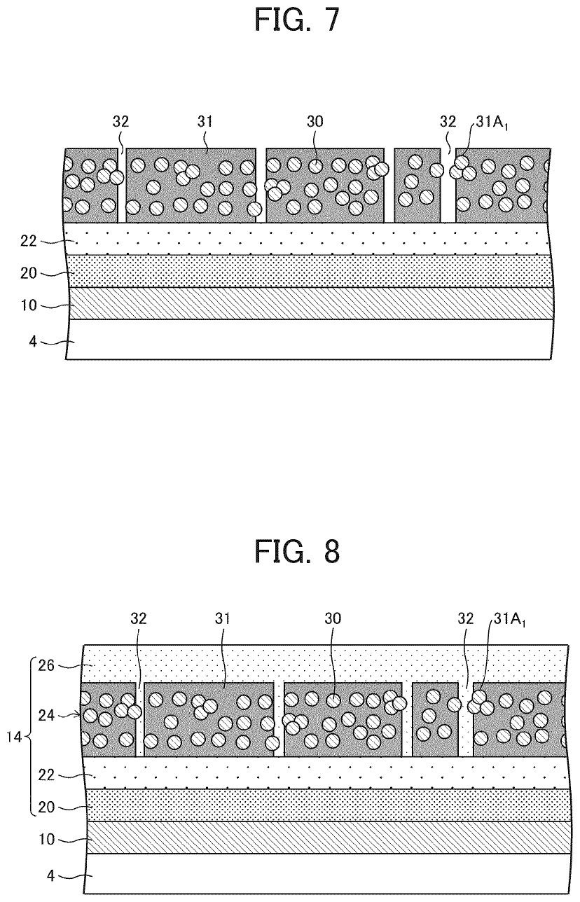

In the step (S124) of forming the emission layer 24 shown in FIGS. 4 and 7, the emission layer 24 including the gaps 32 is formed from the coating layer by heating the coating layer including the quantum dots 30L₁. In the step of forming the emission layer 24, the coating layer is heated at a temperature equal to or higher than the decomposition temperature of the ligands L₁; although the temperature may be designed based on the kind of the ligands L₁, 200 °C or lower, which is non-limiting, is preferable. Heating at this temperature generates the matrix 31 of a metal sulfide derived from the precursor 31P, which is a metal complex included in the coating layer. At this time, the gaps 32, which are cracks randomly formed when viewed from above the emission layer 24, are formed from, as a starting point, either or both of the quantum dots 30 and the aggregates 30A₁ of the quantum dots. Here, the precursor 31P can form the matrix 31 of a metal sulfide as a result of the thermal decomposition. Self-aggregation of the quantum dots 30 and of the metal sulfide contained in the matrix 31 can form the gaps 32 in the emission layer 24. The metal sulfide can be, for example, a sulfide semiconductor of zinc sulfide (ZnS), ZnTeS, ZnMgS₂, MgS, Ga₂S₃, ZnGa₂S₄, or MgGa₂S₄, and crystals thereof can be included in the matrix 31. The coating layer for forming the emission layer 24 preferably contains aggregates of the quantum dots at a volume ratio of 4 to 100 times both inclusive of the primary particles of the quantum dots. This can enhance the gap's occupancy rate.

In the light-emitting element 1 according to the aspect, the matrix 31 fills at least a part of the gap between the quantum dots in the emission layer 24. The matrix is a member containing and retaining another substance, and it can be also referred to as a base, a base material, or a filler. The matrix may be a member containing and retaining a plurality of quantum dots. The matrix may be filled in the emission layer. The matrix may be filled in a region (space) between two of the quantum dots adjacent to each other. The matrix may be filled in a region (space) in the emission layer, other than the region of the plurality of quantum dots. The fact that the matrix is filled between the plurality of quantum dots means that the region between two of the quantum dots adjacent to each other is filled with the matrix, and it is sufficient to know this fact. The matrix exerts a desired effect in at least the region between the two adjacent quantum dots; accordingly, there is not necessarily a need to know that the matrix is filled between all (more than two) quantum dots within a certain range. The outer edge (the upper and lower surfaces) of the emission layer may be covered with the matrix. Further, a portion of the matrix may extend from the outer edge of the emission layer, and a group of the quantum dots may be located away from the outer edge. The outer edge of the emission layer is not formed from only the matrix; the group of the quantum dots may be partly exposed from the matrix. The matrix may be a portion of the emission layer excluding the group of the quantum dots. The matrix may incorporate a plurality of quantum dots. The matrix may be formed so as to partly or completely fill a space formed between two of the quantum dots adjacent to each other. The emission layer may have a clearance. The emission layer may include a plurality of quantum dots, and the matrix may partly or completely fill the region other than the region of the plurality of quantum dots. Each of the two adjacent quantum dots included in the plurality of quantum dots may be buried in the matrix at an interval. The matrix may be the same material as the quantum dot's shell. In this case, the average distance between the mutually adjacent cores of the two adjacent quantum dots (core-to-core distance) may measure 3 nm or more, or 5 nm or more. Alternatively, the average distance between these adjacent cores may be 0.5 times or more of an average core diameter. The core-to-core distance is, for instance, the average of the distances between 20 cores adjacent to each other in a space including the 20 cores. The core-to-core distance may be kept wider than a distance that is produced by shells being in contact with each other. The average core diameter is, for instance, the average of the core diameters of 20 cores in cross-sectional view in a space including the 20 cores. Each core diameter can be defined as the diameter of a circle having the same area as the core's area in cross-sectional view. The matrix may contain a substance different from its main material (e.g., an inorganic substance, such as an inorganic semiconductor) as an additive for instance. The observation result of a part of the emission layer may be applied to the entire emission layer.

The continuous film is a film that cannot be divided by any material other than the materials of the continuous film. The continuous film may be an integral film in which the materials contained in the matrix are coupled together without interruption through chemical bonding. The continuous film of the emission layer 24 measures 1000 nm² or more in area in the direction of a plane orthogonal to the film thickness direction, at any location in the film thickness direction, and the continuous film may be provided with gaps, such as cracks. The matrix may be, for example, an inorganic matrix formed mainly from an inorganic compound. The inorganic compound can be a metal sulfide, such as ZnS. The average thickness of the emission layer 24 may measure 10 to 100 nm both inclusive.

The next (Step S14) is forming the electron transport layer 26, as shown in FIGS. 4 and 8. The electron transport layer 26 may be formed so as to cover the entire emission layer 24 including the gaps 32 on the emission layer 24. The electron transport layer 26 can be formed by, but not limited to, preparing a liquid with an electron transport material dissolved in a solvent, followed by applying this electron-transport-material liquid onto the emission layer 24 and hole transport layer 22, followed by volatilization through heating or other methods to remove the solvent.

The next (Step S16) is forming the cathode 16, as shown in FIGS. 4 and 9. The cathode 16 may be formed by, for instance, forming a thin film made of metal commonly across the individual subpixels through, but not limited to, vacuum evaporation or sputtering. Through the foregoing process steps, the light-emitting element 1 including the emission region 1-LEA is formed.

It is noted that although not shown, the light-emitting element may include forming a sealing layer (Step S18). The sealing layer covers the emission layer 24 and bank 12 and seals the light-emitting element 1. The sealing layer reduces permeation of foreign matters, including moisture, into the emission layer, electron transport layer, and other components from the outside of the sealing layer of the light-emitting element. The sealing layer may have a stacked structure of, for example, an inorganic sealing film made of an inorganic material and an organic sealing film made of an organic material.

### [Light-Emitting Element According to First Modification and Manufacturing Method According to First Modification]

A light-emitting element and a method for manufacturing the light-emitting element according to one modification of the present application are not limited to those according to the first aspect. For instance, the light-emitting element according to the first modification of the present disclosure includes the following in the method for manufacturing the light-emitting element 1 illustrated in FIG. 4: a step (S120) of coating the hole transport layer 22 with a quantum-dot-30L₁ dispersion liquid; a step (S122) of forming a layer including the quantum dots 30L₁ by vaporizing the solvent through at least one of heating and depressurization; and a step (S124) of forming the emission layer 24 provided with the gap 32 by further heating the layer including the quantum dots 30L₁; here, the ligands L₁ contained in the quantum-dot-30L₁ dispersion liquid are ligand materials that are alternative to the foregoing metal complex ligands, and each ligand material can be a silane compound including at least one reactive functional group and at least one coordinating group. Further, the quantum-dot-30L₁ dispersion liquid contains a medium material as the precursor 31P instead of a metal complex, and the medium material can be a silane compound including at least one silicon-bound reactive functional group. For convenience in description, Steps S2 to S10 and Steps S14 to S18, which are the same as those in the first manufacturing method, will not be described, and only Steps S120, S122, and S124, which are included in Step S12 of forming the emission layer 24, will be described. In the step (S120) of coating the dispersion liquid, included in the manufacturing method according to this modification, the quantum dots 30 contained in the quantum-dot-30L₁ dispersion liquid, which are the same as those in the first aspect, will not be described here.

In the quantum-dot-30L₁ dispersion liquid, the ligand material as the ligand L₁ is a silane compound including at least one reactive functional group and at least one coordinating group; for instance, it may include a high-polarity or low-polarity substituent represented by alkyl groups having 1 to 5 carbon atoms.

It is noted that in the Description, for convenience, the ligand material is distinguished from an organic ligand including, similarly, a coordinating group in that the ligand material is a silane compound including a coordinating group.

For example, the ligand material may be a silane compound expressed by Formula 1 below.

R¹ₙSi(R²)ₘ·(R³X)ₚ (Formula 1)

Here, R¹ is a reactive functional group that is bound to Si; further, R² is a high-polarity or low-polarity substituent that is bound to Si; further, X is a coordinating group; further, R³ is, but not limited to, an alkylene group having 1 to 5 carbon atoms, and that is bound to X and silicon; further, n is an integer of 1 to 3; further, m is an integer of 0 to 2; further, p is an integer of 1 to 3; further, a requirement, n+m+p=4 is satisfied.

The ligand material expressed by Formula 1 includes at least one reactive functional group represented by R¹, and the reactive functional group can be selected from the group consisting of a hydroxy group, an amino group, a dimethylamino group, an acetoxy group, a methoxy group, an ethoxy group, hydrogen, a halogen group, and other groups all of which are bound to a silicon atom; here, the halogen group includes chlorine, bromine, and iodine and is preferably chlorine. The silane compound as the ligand material can form a silanol group through hydrolysis of the reactive functional group, and it can form a siloxane binding through dehydration condensation. Accordingly, the ligand material can constitute a part of the matrix 31 (FIG. 7), which is a silicon oxide continuous film incorporating the quantum dots 30.

R² is a high-polarity or low-polarity substituent that is bound to Si; an example is hydrocarbon groups having 1 to 24 carbon atoms. An example of the high-polarity substituent is hydrocarbon groups having 1 to 5 carbon atoms, and an example of the low-polarity substituent is hydrocarbon groups having 6 to 24 carbon atoms; here, the hydrocarbon groups having 6 to 24 carbon atoms may each have an aliphatic cyclic structure or an aromatic cyclic structure.

An example of the coordinating group X included in the ligand material expressed by Formula 1 is at least one coordinating group selected from an amino group, a mercapto group, a carboxylic acid group, a phosphonate group, and other groups, and it is any coordinating group that is bound to the silicon atom of the silane compound via, but not limited to, the alkylene group represented by R³.

More specifically, examples of the ligand material include, but not limited to, (3-mercaptopropyl) trimethoxysilane, (3-aminopropyl) trimethoxysilane, 3-mercaptopropyl (dimethoxy) methylsilane, 3-aminopropyl (dimethoxy) methylsilane, (3-mercaptopropyl) triethoxysilane, (3-aminopropyl) triethoxysilane, 3-aminopropyl (diethoxy) methylsilane, 3-mercaptopropyl (diethoxy) methylsilane, and N-(2-aminoethyl)-3-aminopropyltrimethoxysilane; two or more kinds of silane compounds as the ligand material may be used in combination.

The concentration of the quantum dots 30 contained in the quantum-dot-30L₁ dispersion liquid, which is used for manufacturing the light-emitting element 1 according to this modification, is a non-limiting value within a range of, for instance, 1.4 to 12.5 parts by mass with respect to the total of the quantum dots 30 and solvent standing at 100 parts by mass. This can form the emission layer 24 incorporating the quantum dots 30 and produce the cracks by heating the emission layer 24.

A medium material as the precursor 31P may be further dissolved in the quantum-dot-30L₁ dispersion liquid according to this modification. Here, the medium material as the precursor 31P can be a silane compound including at least one silicon-bound reactive functional group, expressed by Formula 2 below.

R(SiR₂)_{q}·R, or R₃SiO_{1/2} (Formula 2)

In Formula 2, R is either R¹ or R², each of which is bound to Si; further, R¹ is selected from reactive functional groups expressed by Formula 1 above; further, R² is selected from high-polarity or low-polarity substituents described above; further, q is an integer that is 1 or 2; further four to six Rs are included.

The silane compound being the medium material expressed by Formula 2 can be, more specifically, for example, dimethoxydimethylsilane, tetramethyl orthosilicate, tetraethyl orthosilicate, hexamethoxydisiloxane, diphenylsilanediol, phenyltrimethoxysilane, dimethoxymethylphenylsilane, octyltrimethoxysilane, decyltrimethoxysilane, tetrachlorosilane, 1,2-dichloro-1,1,2,2-tetramethylsilane, 1,1,2,2-tetrachloro-1,2-dimethylsilane, hexachlorodisilane, and octadecyltrichlorosilane. It is more desirable that the silane compound be dimethoxydimethylsilane, tetramethyl orthosilicate, tetraethyl orthosilicate, or hexamethoxydisiloxane.

Since the precursor 31P is a medium material, the medium materials and/or the medium material and the foregoing ligand material are bound together, so that the matrix 31 that is an inorganic matrix having a Si—O—Si network (siloxane network) can be formed.

When the precursor 31P contained in the quantum-dot-30L₁ dispersion liquid is a medium material, its concentration may be any value within a range of, for instance, 1 to 100 parts by mass with respect to the quantum dots 30L₁ of 100 parts by mass; it is more desirable that the concentration be within a range of 1 to 50 parts by mass. This can form the emission layer 24 and produce the cracks.

In the manufacturing method according to this modification, the solvent that disperses the quantum dots 30L₁ and dissolves the precursor 31P may be selected from the solvents used in the method for manufacturing the light-emitting element according to the first aspect; for instance, the solvent is preferably a non-polar solvent or a low-polarity solvent; it is more desirable that the solvent be selected from hexane, octane, decane, toluene, xylene, chloroform, chlorobenzene, bromobenzene, and iodobenzene.

Other than the foregoing, the quantum-dot-30L₁ dispersion liquid in the manufacturing method according to this modification may contain substances, such as halogen (chlorine, bromine, or iodine) ions.

Like that in the first aspect, the coating of the quantum-dot-30L₁ dispersion liquid onto the hole transport layer 22 can be performed through a publicly known coating method, such as spin coating, slit coating, or inkjet printing.

In the step (S122) of forming the layer including the quantum dots 30L₁, the solvent, like that in the first aspect, may be removed from the quantum-dot-30L₁ dispersion liquid coated on the hole transport layer 22 by either or both of heating and depressurization. This agglomerates some of the quantum dots 30L₁ within the coating layer of the quantum dots 30L₁, so that the aggregates 30A₁ of the quantum dots can be formed. The condition of drying (preliminary-drying condition) the coating layer formed by applying the quantum-dot-30L₁ dispersion liquid is non-limiting, but the condition of heating the same may be any temperature lower than a temperature at which hydrolysis and dehydration condensation of the ligand materials, which are the ligands L₁, and/or the medium material, which is the precursor 31P, occur; the heating can be performed at 50 to 80 °C.

In the step (S124) of forming the emission layer 24, the emission layer 24 including the gaps 32 is formed from the coating layer by heating the coating layer including the quantum dots 30L₁. In the step of forming the emission layer 24, the coating layer is heated at a temperature equal to or higher than a temperature at which hydrolysis and dehydration condensation of the ligand materials, which are the ligands L₁, and the medium material occur; although the temperature may be designed based on the kind of the ligand materials and the kind of the medium material, 80 °C or higher, which is non-limiting, is preferable, and 100 °C or higher, which is non-limiting, is more desirable. Further, the coating layer is heated at a non-limiting temperature within 200 °C or lower. Heating at this temperature generates, in the coating layer, the matrix 31 of a silicon oxide derived from a siloxane network formed by the silane compounds included as the ligand materials and as the medium material. At this time, the gaps 32, which are cracks randomly formed when viewed from above the emission layer 24, are formed from, as a starting point, either or both of the quantum dots 30 and the aggregates 30A₁ of the quantum dots. Self-aggregation of the quantum dots 30 and of the siloxane network included in the matrix 31 of a silicon oxide can form the gaps 32 in the emission layer 24. Like that in the first aspect, the coating layer for forming the emission layer 24 preferably includes an aggregate of the quantum dots at a volume ratio of 4 to 100 times both inclusive of the primary particles of the quantum dots. This can enhance the gap's occupancy rate.

### [Light-Emitting Element According to Second Aspect and Manufacturing Method According to Second Aspect]

A light-emitting element and a method for manufacturing the light-emitting element according to one aspect is not limited to those according to the first aspect. For instance, the light-emitting element 1A according to a second aspect of the present disclosure may include the quantum dots 30(L₂, L₃) including the low-polarity ligands L₂ and high-polarity ligands L₃ in the emission layer 24A included in the light-emitting element 1A, and the gaps 32 may be formed from, as a starting point, aggregates 30A₂ of the quantum dots 30(L₂, L₃). For convenience in description, Steps S2 to S10 and Steps S14 to S18, which are the same as those in the first manufacturing method, will not be described, and only Step S12, i.e., forming the emission layer 24A, will be described.

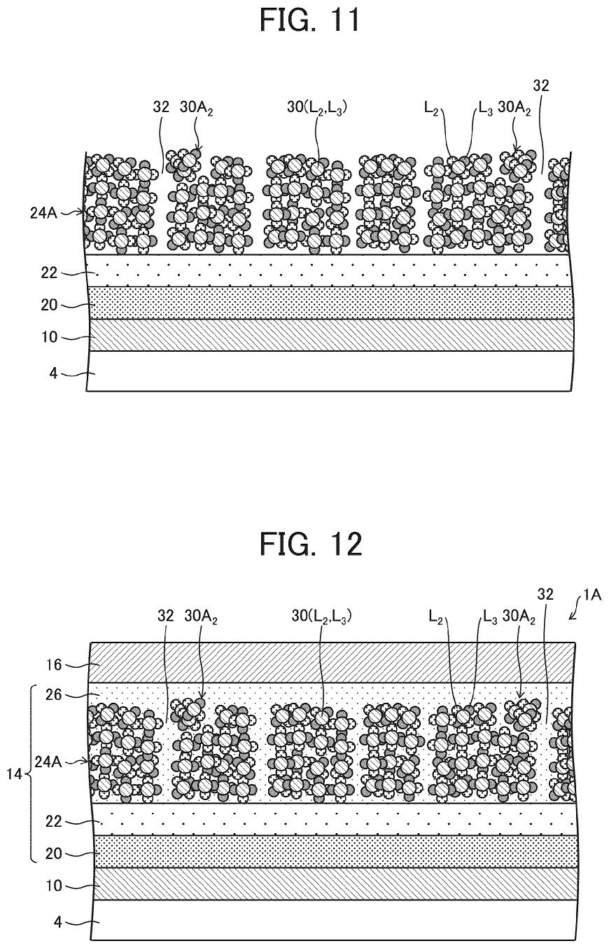

As shown in FIGS. 10 and 11, a method of forming the emission layer 24A in the manufacturing method according to the second aspect is forming a coating layer including the quantum dots 30(L₂, L₃), by applying a quantum-dot-30(L₂, L₃) dispersion liquid with the ligands L₂ and ligands L₃ being coordinated.

The quantum dots 30(L₂, L₃) include the ligands L₂ as organic ligands; each ligand L₂ may include the coordinating group, of foregoing L₁, selected from the group consisting of the amino group, mercapto group, carboxylic acid group, and phosphonate group, a coordinating group selected from the group consisting of an amino group, a mercapto group, a carboxylic acid group, and a phosphonate group, or a coordinating group selected from a dithiocarboxylic acid group, a xanthogenic acid group, and a thiourea group. Further, the ligand L₂ may include a hydrocarbon group having 6 to 24 carbon atoms. That is, the ligands L₂ are selected from low-polarity ligands whose polarity is relatively low among foregoing L₁.

The quantum dots 30(L₂, L₃) include the ligands L₃ as organic ligands; each ligand L₃ may include a coordinating group selected from the group consisting of an amino group, a mercapto group, a carboxylic acid group, and a phosphonate group, or a coordinating group selected from a dithiocarboxylic acid group, a xanthogenic acid group, and a thiourea group. Further, the ligand L₃ may include a hydrocarbon group having 1 to 5 carbon atoms; here, the ligand L₃ may be structured such that at least one hydrogen atom within the hydrocarbon group having 1 to 5 carbon atoms is substituted by a hydroxyl group. That is, the ligands L₃ are selected from, among the foregoing ligands L₁, high-polarity ligands whose polarity is higher than that of the ligands L₂.

The difference in the number of carbon atoms of the hydrocarbon group in each of the ligands L₂ and L₃ more desirably stands at 5 or more for instance, because such a difference enables, during the solvent removal from the quantum-dot-30(L₂, L₃) dispersion liquid, the aggregates 30A₂ to be formed, and the gaps 32 to be formed from, as a starting point, the aggregates 30A₂.

In the quantum dot 30(L₂, L₃), the ratio between the ligands L₂, which are selected from low-polarity organic ligands, and the high-polarity ligands L₃, whose polarity is high, may be selected in accordance with the polarity of a solvent for dispersing the quantum dots 30(L₂, L₃). When a non-polar solvent or low-polarity solvent for instance is used as the solvent for dispersing the quantum dots 30(L₂, L₃), the mass ratio between the low-polarity ligands L₂ and the high-polarity ligands L₃ preferably falls within 1:1 to 4:1 as L₂:L₃; within this range, the larger the mass ratio of the high-polarity ligands L₃ is, the more suitably the aggregates 30A₂ can be formed after the application of the quantum-dot-30(L₂, L₃) dispersion liquid.

Further, when a high-polarity solvent for instance is used as the solvent, the mass ratio between the ligands L₂, which are selected from low-polarity ligands, and the high-polarity ligands L₃ preferably falls within 1:1 to 4:1 as L₂:L₃; within this range, the larger the mass ratio of the high-polarity ligands L₃ is, the more suitably the aggregates 30A₂ can be formed after the application of the quantum-dot-30(L₂, L₃) dispersion liquid.

The concentration of the quantum dots 30(L₂, L₃) contained in the quantum-dot-30(L₂,L₃) dispersion liquid is a non-limiting value within a range of, for instance, 1.4 to 12.5 parts by mass with respect to the total of the quantum dots 30(L₂, L₃) and solvent standing at 100 parts by mass. This can form the emission layer 24A with the gaps 32 formed due to the aggregates 30A₂, which are the aggregated quantum dots 30.

The solvent contained in the quantum-dot dispersion liquid containing the quantum dots 30(L₂, L₃) may be at least one selected from a non-polar solvent and a low-polarity solvent. The non-polar solvent can be selected from aliphatic hydrocarbon solvents, such as hexane, cyclohexane, and methylcyclohexane, and aromatic hydrocarbon solvents, such as toluene and xylene. Further, examples of the low-polarity solvent include the foregoing halogenated aromatic hydrocarbon solvents, halogenated aliphatic hydrocarbon solvents, and ether solvents.

The solvent contained in the quantum-dot dispersion liquid containing the quantum dots 30(L₂, L₃) may be at least one selected from high-polar solvents. Examples of the high-polar solvents include the following: amide solvents, such as dimethylformamide (DMF), N-methylformamide (NMF), and N-methyl-2-pyrrolidone (NMP); ester solvents, such as ethyl acetate and butyl acetate; ketone solvents, such as acetone and methylethyl ketone; sulfoxide solvents, such as dimethyl sulfoxide (DMSO); ether solvents, which are known as high solvents, such as tetrahydrofuran (THF); thioether solvents, such as diethyl sulfide (DES); and nitrile solvents, such as acetonitrile and propionitrile.

The quantum-dot-30(L₂, L₃) dispersion liquid, which contains the ligands L₂ and L₃ whose polarities are different from each other, enables the aggregates 30A₂ as the aggregated quantum dots 30(L₂, L₃) to be formed in the coating layer of the quantum-dot dispersion liquid, as illustrated in FIG. 11; at this time, the emission layer 24A including the gaps 32 formed from, as a starting point, the aggregates 30A₂ of the quantum-dot-30(L₂, L₃) dispersion liquid can be formed. Thereafter, an electron transport layer and a cathode are formed in line with a procedure similar to that in the first aspect, as illustrated in FIG. 12, and the light-emitting element 1A can be thus manufactured.

It is noted that the quantum-dot-30(L₂, L₃) dispersion liquid may contain a metal complex, which is the foregoing precursor. Although not limited, the precursor may be contained within, for instance, a range of 0 to 100 parts by mass with respect to the quantum dots (L₂, L₃) of 100 parts by mass. Accordingly, a continuous film of a metal sulfide may be formed in the emission layer 24A.

### [Light-Emitting Element According to Second Modification and Manufacturing Method According to Second Modification]

A light-emitting element and a method for manufacturing the light-emitting element according to one aspect of the present disclosure are not limited to those according to the first and second aspects and the first modification. For instance, the light-emitting element 1A according to a second modification of the present disclosure may include the quantum dots 30(L₂, L₃) including the low-polarity ligands L₂ and high-polarity ligands L₃ in the emission layer 24A included in the light-emitting element 1A, and the gaps 32 may be formed from, as a starting point, the aggregates 30A₂ of the quantum dots 30(L₂, L₃); here, a low-polarity ligand material, which is the ligand L₂, is a silane compound including at least one reactive functional group, at least one substituent, and at least one coordinating group; here, the substituent is a low-polarity substituent and may be a hydrocarbon group having 6 to 24 carbon atoms. Further, a high-polarity ligand material, which is the ligand L₃, is a silane compound including at least one reactive functional group, at least one substituent, and at least one coordinating group; here, the substituent is a high-polarity substituent and may be a hydrocarbon group having 1 to 5 carbon atoms.

In the emission layer 24A in a manufacturing method according to the second modification, a coating layer including the quantum dots 30(L₂, L₃) is formed (S120 in FIG. 4) by applying a quantum-dot-30(L₂, L₃) dispersion liquid with the ligands L₂, which are low-polarity ligand materials, and the ligands L₃, which are high-polarity ligand materials, being coordinated.

Each low-polarity ligand material as the ligand L₂ may be a silane compound expressed by Formula 1-2 below.

R¹ₙSi(R²¹)ₘ·(R³¹X)ₚ (Formula 1-2)

In Formular 1-2, R¹ is a reactive functional group that is bound to Si; further, R²¹ is a high-polarity or low-polarity substituent that is bound to Si; further, X is a coordinating group; further, R³¹ is a hydrocarbon group having 6 to 24 carbon atoms, and that is bound to X and silicon; further, n is an integer of 1 to 3; further, m is an integer of 0 to 2; further, p is an integer of 1 to 3; further, a requirement, n+m+p=4 is satisfied.

The ligand material expressed by Formula 1-2 includes at least one reactive functional group represented by R¹, and like that in foregoing Formula 1, the reactive functional group can be selected from the group consisting of a hydroxy group, an amino group, a dimethylamino group, an acetoxy group, a methoxy group, an ethoxy group, hydrogen, a halogen group, and other groups, all of which are bound to a silicon atom; here, the halogen group includes chlorine, bromine, and iodine and is preferably chlorine. R²¹ is a low-polarity substituent that is bound to Si; an example is hydrocarbon groups having 6 to 24 carbon atoms. The hydrocarbon groups having 6 to 24 carbon atoms may each have an aliphatic cyclic structure or an aromatic cyclic structure.

An example of the coordinating group X included in the ligand material expressed by Formula 1-2 is at least one coordinating group selected from a mercapto group, an amino group, a carboxylic acid group, a phosphonate group, and other groups, and it is any coordinating group that is bound to the silicon atom of the silane compound via, but not limited to, the hydrocarbon group represented by R³¹.

More specifically, a non-limiting example of the low-polarity ligand material is N-(2-aminoethyl)-3-aminopropyltrimethoxysilane.

Each high-polarity ligand material as the ligand L₃ may be a silane compound expressed by Formula 1-3 below.

R¹ₙSi(R²²)ₘ·(R³²X)ₚ (Formula 1-3)

In Formular 1-3, R¹ is a reactive functional group that is bound to Si; further, R²² is a high-polarity substituent that is bound to Si; further, X is a coordinating group; further, R³² is a hydrocarbon group having 1 to 5 carbon atoms, and that is bound to X and silicon; further, n is an integer of 1 to 3; further, m is an integer of 0 to 2; further, p is an integer of 1 to 3; further, a requirement, n+m+p=4 is satisfied.

An example of the coordinating group X included in the ligand material expressed by Formula 1-3 is at least one coordinating group selected from an amino group, a mercapto group, a carboxylic acid group, a phosphonate group, and other groups, and it is any coordinating group that is bound to the silicon atom of the silane compound via, but not limited to, the alkylene group represented by R³². R²² is a low-polarity substituent that is bound to Si; an example is a hydrocarbon group having 1 to 5 carbon atoms.

More specifically, examples of the high-polarity ligand material include, but not limited to, (3-mercaptopropyl) trimethoxysilane, (3-aminopropyl) trimethoxysilane, 3-mercaptopropyl (dimethoxy) methylsilane, 3-aminopropyl (dimethoxy) methylsilane, (3-mercaptopropyl) triethoxysilane, (3-aminopropyl) triethoxysilane, 3-aminopropyl (diethoxy) methylsilane, and 3-mercaptopropyl (diethoxy) methylsilane.

In the quantum dots 30(L₂, L₃) according to this modification, the mass ratio between the low-polarity ligand materials, which are the ligands L₂, and the high-polarity ligand materials, which are the ligands L₃, may be selected in accordance with the polarity of a solvent for dispersing the quantum dots 30(L₂, L₃). For instance, when a non-polar solvent or a low-polarity solvent is used, the mass ratio between the low-polarity ligands L₂ and the high-polarity ligands L₃ preferably falls within 1:1 to 4:1 as L₂:L₃, like that in the manufacturing method according to the second aspect; within this range, the larger the mass ratio of the high-polarity ligands L₃ is, the more suitably the aggregates 30A₂ can be formed after the application of the quantum-dot-30(L₂, L₃) dispersion liquid.

Further, when a high-polarity solvent for instance is used as the solvent in this modification, the mass ratio between the ligands L₂, which are selected from low-polarity ligands, and the high-polarity ligands L₃ preferably falls within 1:1 to 4:1 as L₂:L₃, like that in the manufacturing method according to the second aspect; within this range, the larger the mass ratio of the high-polarity ligands L₃ is, the more suitably the aggregates 30A₂ can be formed after the application of the quantum-dot-30(L₂, L₃) dispersion liquid.

It is noted that the quantum-dot-30(L₂, L₃) dispersion liquid may contain a medium material, which is a precursor for forming the foregoing matrix of a silicon oxide. Although not limited, the precursor may be contained within, for instance, a range of 0 to 100 parts by mass with respect to the quantum dots (L₂, L₃) of 100 parts by mass. Accordingly, a continuous film of a siloxane network may be formed in the emission layer 24A.

The quantum dots 30 in this modification may be each coordinated with the low-polarity organic ligand used in the light-emitting element according to the second aspect; this organic ligand is selected from low-polarity ligands whose polarity is relatively low, and each of which includes a coordinating group selected from the group consisting of an amino group, a mercapto group, a carboxylic acid group, and a phosphonate group and includes a hydrocarbon group having 6 to 24 carbon atoms; specific examples include octylthiol and oleic acid.

In the step (S124) of forming the emission layer 24A, like that in the first modification, the step of forming the emission layer 24A may include heating the coating layer at a temperature equal to or higher than a temperature at which hydrolysis and dehydration condensation of the ligand materials, which are the ligands L₂ and L₃, and of the medium material occur; although not limited, the temperature preferably stands at 80 °C or higher; it is more desirable the heating be performed at 100 °C or a higher temperature. Heating at this temperature generates, in the coating layer, the matrix 31 of a silicon oxide derived from a siloxane network formed by silane compounds, which are included as ligand materials that are the ligands L₂ and L₃. At this time, the gaps 32, which are cracks randomly formed when viewed from above the emission layer 24A, are formed from, as a starting point, either or both of the quantum dots 30 and the aggregates 30A₁ of the quantum dots. Self-aggregation of the quantum dots 30 and of the siloxane network included in the matrix 31 of a silicon oxide can form the gaps 32 in the emission layer 24A.

### (Inorganic Matrix Included in Light-Emitting Element According to Another Aspect)

It is noted that other than an inorganic matrix formed from a metal sulfide, such as ZnS, and an inorganic matrix formed from a silicon oxide, the inorganic matrix can be an inorganic matrix mainly containing at least one of a Group II-VI compound, a Group II oxide, a Group III oxide, and a Group IV oxide. For instance, the inorganic matrix can contain one or more selected from the group consisting of titanium oxide (TiO₂), aluminum oxide (Al₂O₃), boron oxide (B₂O₃), phosphorus oxide (P₂O₅), germanium oxide (GeO₂), hafnium oxide (HfO₂), zinc oxide (ZnO), zirconium oxide (ZrO₂), tellurium oxide (TeO₂), bismuth oxide (Bi₂O₃), vanadium oxide (V₂O₅), antimony oxide (Sb₂O), lead oxide (PbO), copper oxide (CuO), copper iodide (I) (CuI), and silver iodide (I) (AgI).

Although the light-emitting elements 1 and 1A including a top-emission light-emitting element and their manufacturing methods have been described in FIGS. 1 to 12, a light-emitting element according to one aspect is not limited to a top-emission light-emitting element; it may be a bottom-emission light-emitting element. The light-emitting element in this case may be structured such that its cathode is disposed above its anode, such that the anode is formed from an electrode material that transmits visible light, and such that the cathode is formed from an electrode material that reflects visible light.

In one aspect, although the light-emitting element may have a known stacked structure by way of example, the light-emitting element may have an inverted stacked structure. Although not shown, a light-emitting element having an inverted stacked structure can be formed by stacking an electron transport layer, an emission layer, a hole transport layer, a hole injection layer, and an anode sequentially from a cathode provided on a substrate. It is noted that in the light-emitting element having an inverted stacked structure, the hole transport layer may be filled in a gap provided in the emission layer.

### [Action and Effect]

In the configurations and manufacturing methods according to the foregoing aspects, using a quantum-dot emission layer including a gap causes light scattering at the interface of the emission layer including the gap, thereby offering a light-emitting element with improved efficiency of light extraction in the emission layer. This offers the light-emitting element with enhanced external quantum efficiency.

Further, a display device including the foregoing light-emitting elements is included in one aspect of the present disclosure. Providing these light-emitting elements offers a QLED display device with improved luminance.

The present disclosure is not limited to the foregoing aspects. Various modifications can be made within the scope of the claims. An aspect that is obtained in combination as appropriate with the technical means disclosed in the respective aspects is also encompassed within the technical scope of the present disclosure. Furthermore, combining the technical means disclosed in the respective aspects can form a new technical feature.

### EXAMPLES

One example of the present disclosure will be described below.

A light-emitting element according to Example 1 with a crack formed in its emission layer, a light-emitting element according to Example 2 with a crack formed in its emission layer, and a light-emitting element according to Comparative Example 1 with no crack formed in its emission layer were produced, and evaluations were made on their voltage-current density characteristics, luminance-current density characteristics, and external quantum efficiency (EQE)-current density characteristics.

### (Preparation of Composition for Emission Layer)

### Example 1

After 4 mg of quantum dots of InP (cores) and ZnS (shells) and 150 mg of zinc isopropylxanthate were stirred in DMF, the quantum dots of InP/ZnS underwent centrifugal separation to be precipitated, and the DMF was removed. The quantum dots of InP/ZnS with the DMF removed therefrom were redispersed in 0.2 ml of chlorobenzene to prepare a quantum-dot dispersion liquid (Sample 1) for forming the light-emitting element according to Example 1.

Through DLS, it was found that an aggregate of the quantum dots of InP (cores) and ZnS (shells) was contained in the quantum-dot dispersion liquid in Sample 1. Through the DLS, it was found that the median particle diameters (D50) of the primary particles on a volumetric basis measured 8.4 nm, and that the aggregate's size was approximately 20 times larger than D50.

### Example 2

After 4 mg of quantum dots of InP (cores) and ZnS (shells) and 150 mg of (3-mercaptopropyl)trimethoxysilane were stirred in DMF, the quantum dots of InP/ZnS underwent centrifugal separation to be precipitated, and the DMF was removed. The quantum dots of InP/ZnS with the DMF removed therefrom were redispersed in 0.2 ml of chlorobenzene, followed by adding 4 mg of tetramethyl orthosilicate thereto, to prepare a quantum-dot dispersion liquid (Sample 2) for forming the light-emitting element according to Example 2.

### Comparative Example 1

Here, 4 mg of quantum dots of InP (cores) and ZnS (shells) were dissolved in 0.2 ml of chlorobenzene to prepare a quantum-dot dispersion liquid (Comparative Sample 1) for forming the light-emitting element according to Comparative Example 1.

### (Production of Light-Emitting Elements)

The individual compositions in Example 1 were used to form the light-emitting element including a cathode, an electron transport layer (ETL), an emission layer (EML), a hole transport layer (HTL), a hole injection layer (HIL), and an anode.

Materials for forming the respective layers are listed below.
Cathode: Ag
Electron Transport Layer: MgZnO
Emission Layer: Sample 1, Sample 2, or Comparative Sample 1
Hole Transport Layer: TFB (manufactured by American Dye Source)
Hole Injection Layer: Complex of PEDOT and PSS
Bank: Polyimide
Anode: ITO/Ag
Substrate: Glass

A Ag/ITO anode and a bank underwent patterning onto a 5 cm×5 cm substrate, and a hole injection layer and a hole transport layer were formed in the stated order onto the formed anode. Next, the quantum-dot dispersion liquid of Sample 1 was spin-coated onto the hole transport layer, followed by drying through heating at 130 °C for 5 minutes (preliminary drying). The substrate coated with Sample 1 underwent further heating at 150 °C for 30 minutes to form an emission layer with a crack on its surface. Subsequently, a liquid containing 20 mg of MgZnO, which is a material for an electron transport layer, dissolved in 1 ml of a solvent was spin-coated onto the formed emission layer, followed by drying through heating to form the electron transport layer, and further forming a cathode, thus forming the light-emitting element according to Example 1.

Likewise, the light-emitting elements according to Sample 2 and Comparative Example 1 were produced in line with the same procedure as that in the light-emitting element according to Example 1 with the exception that Sample 2 or Comparative Sample 1 was used instead of Sample 1.

It is noted that Table 1 below shows evaluations through photoelectron yield spectroscopy (PYS) and ultraviolet-visible spectroscopy (UV-vis), on the HOMO and LUMO of TFB, which constitutes the hole transport layer, and on the HOMO and LUMO of MgZnO, which constitutes the electron transport layer.

TABLE 1

| | HOMO | LUMO |
|---|---|---|
| HOLE TRANSPORT | 5.4 eV | 2.5 eV |
| LAYER | | |
| ELECTRON TRANSPORT | 7.2 eV | 3.5 eV |
| LAYER | | |
| HOMO'S DIFFERENCE OR | 1.8 eV | 1.0 eV |
| LUMO'S DIFFERENCE | | |

### [Refractive Index Evaluations]

For each of the emission layers according to Example 1, Example 2, and Comparative Example 1, the difference between the average refractive index and the refractive index of the material of the emission layer was measured using an ellipsometer M-2000 (manufactured by J.A.Woollam Japan).

A target object obtained by spin-coating the quantum-dot dispersion liquid of Sample 1 onto the hole transport layer produced in line with the procedure described earlier (the production of the light-emitting element), followed by drying through heating at 130 °C for 5 minutes underwent a measurement on its refractive index as the refractive index of the material of the emission layer. The next was subjecting the emission layer in Sample 1 whose refractive index had been measured, to further heating at 150 °C for 30 minutes to form an emission layer with a crack on its surface, and then, the average refractive index of the emission layer was measured to determine the difference between the average refractive index of the emission layer formed from Sample 1 and the refractive index of the material of the emission layer. With the exception that Comparative Sample 1 was used, a target object obtained under the same condition as that in Sample 1, i.e., by drying through heating at 130 °C for 5 minutes underwent a measurement on its refractive index as the refractive index of the emission layer, followed by subjecting the emission layer heated at 150 °C for 30 minutes to a measurement on its average refractive index, to determine the difference between the average refractive index of the emission layer formed from Comparative Sample 1 and the refractive index of the material of the emission layer.

Table 2 below shows the evaluations on the difference between the average refractive index of each emission layer and the refractive index of the material of the emission layer.

TABLE 2

| | | | DIFFERENCE |
|---|---|---|---|
| | | | BETWEEN |
| | EMISSION | REFRACTIVE | AVERAGE |
| | LAYER'S | INDEX OF | REFRACTIVE |
| | AVERAGE | EMISSION | INDEX AND |
| | REFRACTIVE | LAYER'S | REFRACTIVE |
| | INDEX | MATERIAL | INDEX |
| SAMPLE 1 | 2.2 | 1.9 | 0.3 |
| COMPARATIVE | 2.0 | 2.0 | 0 |
| SAMPLE 1 | | | |

[Imaging with Fluorescent Microscope and Evaluations of Crack's Occupancy Rate on Emission Layer's Surface]

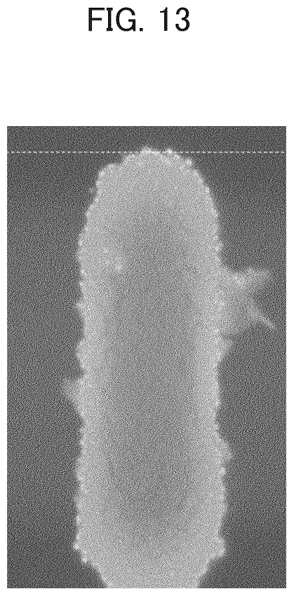

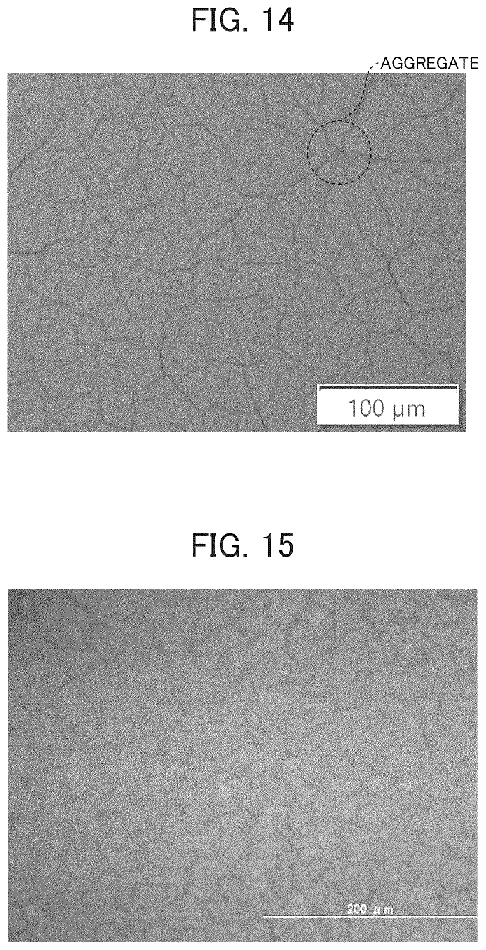

The light-emitting elements according to Example 1 and Example 2 underwent fluorescence-microscope imaging to obtain images of their emission layer's surfaces. FIG. 13 shows a fluorescent-microscope image of the light-emitting element's surface of the light-emitting element according to Example 1, FIG. 14 shows an enlarged fluorescent-microscope image of the surface of the light-emitting element according to Example 1, and FIG. 15 shows an enlarged fluorescent-microscope image of the surface of the light-emitting element according to Example 2. As shown in FIGS. 13 to 15, it was found that minute cracks were formed randomly on the light-emitting element's surfaces of the light-emitting elements according to Example 1 and Example 2.

Next, the crack's occupancy rate on the emission layer's surface was evaluated. The image data obtained from the picture of the light-emitting element taken by the fluorescent microscope underwent grayscale conversion, and the crack's occupancy rate on the emission layer's surface was determined from the obtained binary data. The crack's occupancy rate determined from the picture of the light-emitting element stood at 5.2% in Example 1.

### [Evaluations of Crack's Width on Emission Layer's Surface]

For the light-emitting layer according to Example 1, the image data obtained from the picture of the light-emitting element taken by the fluorescent microscope underwent grayscale conversion, and the crack's width on the emission layer's surface was determined from the obtained binary data. The maximum crack having a length satisfying a condition, 62.5 μm was identified and underwent a measurement on the crack's maximum width. It was found that the maximum value of the crack's width determined on the light-emitting element according to Example 1 measured 2 μm, which was larger than the wavelength, 634 nm, of light emitted by the light-emitting element according to Example 1.

### [Evaluations on Current Density-External Quantum Efficiency]

Each of the light-emitting elements in Examples 1 and Comparative Example 1 underwent an evaluation on its current density-external quantum efficiency (EQE) characteristic. The evaluation of the current density-external quantum efficiency was performed using an IVL-characteristic evaluation apparatus.

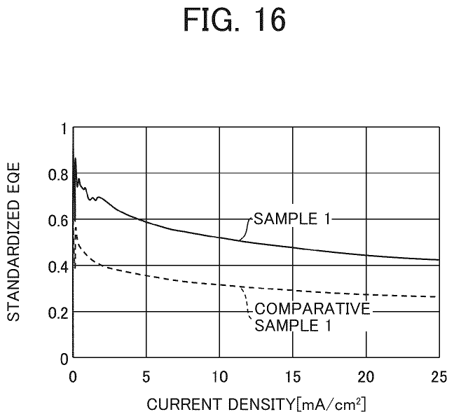

FIG. 16 is a graph showing the current density-external quantum efficiency (EQE) characteristics of the light-emitting elements according to Example 1 and Comparative Example 1. As shown in FIG. 16, in the current density-external quantum efficiency (EQE) characteristics, the external quantum efficiency of the light-emitting element according to Example 1 with a crack, which is a gap, formed in its emission layer is higher than the external quantum efficiency characteristic of the light-emitting element according to Comparative Example 1.

1. A light-emitting element comprising a stack of an anode, a cathode, and a functional layer, the functional layer being positioned between the anode and the cathode,
wherein the functional layer includes an emission layer,
the emission layer includes quantum dots and an inorganic matrix,
the emission layer includes an emission region in a portion where the anode and the cathode face each other, and
the emission layer is divided by a gap extending from a front surface of the emission region to a back surface of the emission region.

2. The light-emitting element according to claim 1, wherein the inorganic matrix includes a matrix of a Group II-VI compound.

3. The light-emitting element according to claim 2, wherein the matrix of the Group II-VI compound includes a continuous film of a metal sulfide incorporating the quantum dots.

4. The light-emitting element according to claim 2, wherein
the matrix of the Group II-VI compound includes a metal sulfide derived from a metal complex, and
the metal complex includes a coordinating group selected from a dithiocarboxylic acid group, a xanthogenic acid, and a thiourea group and includes a hydrocarbon group having 1 to 24 carbon atoms.

5. The light-emitting element according to claim 4, wherein the hydrocarbon group is selected from hydrocarbon groups having 1 to 5 carbon atoms.

6. The light-emitting element according to claim 4, wherein the hydrocarbon group is selected from hydrocarbon groups having 6 to 24 carbon atoms.

7. The light-emitting element according to claim 1, wherein the inorganic matrix includes a matrix of a Group IV oxide.

8. The light-emitting element according to claim 7, wherein the matrix of the Group IV oxide includes a continuous film of a silicon oxide incorporating the quantum dots.

9. The light-emitting element according to claim 7, wherein
the matrix of the Group IV oxide is a matrix derived from a precursor of a silicon oxide, and
the precursor contains a silane compound including at least one reactive functional group selected from a silicon-bound hydroxy group, a silicon-bound amino group, a silicon-bound dimethylamino group, a silicon-bound acetoxy group, a silicon-bound methoxy group, a silicon-bound ethoxy group, silicon-bound hydrogen, and a silicon-bound halogen group.

10. The light-emitting element according to claim 9, wherein the silane compound includes at least one coordinating group selected from a mercapto group and an amino group.

11. A light-emitting element comprising a stack of an anode, a cathode, and a functional layer, the functional layer being positioned between the anode and the cathode,
wherein the functional layer includes an emission layer,
the emission layer includes a ligand material coordinating with quantum dots,
the emission layer includes an emission region in a portion where the anode and the cathode face each other,
the emission layer is divided by a gap extending from a front surface of the emission region to a back surface of the emission region,
the ligand material includes a ligand material of high polarity, and
the ligand material of high polarity contains a silane compound including
at least one coordinating group selected from the group consisting of a mercapto group and an amino group,
at least one reactive functional group selected from a silicon-bound hydroxy group, a silicon-bound amino group, a silicon-bound dimethylamino group, a silicon-bound acetoxy group, a silicon-bound methoxy group, a silicon-bound ethoxy group, and a silicon-bound halogen group, and
at least one hydrocarbon group having 1 to 5 carbon atoms.

12. The light-emitting element according to claim 11, comprising a matrix of a silicon oxide derived from the ligand material of high polarity.

13. The light-emitting element according to claim 11, wherein
the emission layer further includes an organic ligand of low polarity coordinating with a quantum dot, and
the organic ligand of low polarity includes at least one hydrocarbon group having 6 to 24 carbon atoms.

14. The light-emitting element according to claim 11, wherein
the ligand material of low polarity contains a silane compound including
at least one coordinating group selected from the group consisting of a mercapto group and an amino group,
at least one reactive functional group selected from a hydroxy group, an amino group, a dimethylamino group, an acetoxy group, a methoxy group, an ethoxy group, hydrogen, and a halogen group, and
at least one hydrocarbon group having 6 to 24 carbon atoms.

15. The light-emitting element according to claim 14, comprising a matrix of a silicon oxide derived from the ligand material of low polarity.

16. The light-emitting element according to claim 11, comprising a matrix of a silicon oxide derived from a medium material containing a silane compound including at least one reactive functional group selected from a silicon-bound methoxy group, a silicon-bound ethoxy group, a silicon-bound hydroxyl group, and a silicon-bound halogen group.

17-19. (canceled)

20. The light-emitting element according to claim 1, wherein an area ratio of the gap occupying a surface of the emission region is 5 to 10% both inclusive.

21. The light-emitting element according to claim 1, wherein a width of the gap is larger than a wavelength of light emitted by the quantum dots.

22. (canceled)

23. The light-emitting element according to claim 1, wherein the gap is a crack dividing the emission region randomly.

24. (canceled)

25. The light-emitting element according to claim 1, comprising, as the functional layer, a hole transport layer and an electron transport layer,
wherein the hole transport layer is provided between the anode and the emission layer,
the electron transport layer is provided between the cathode and the emission layer,
a difference between a HOMO of a material of the hole transport layer and a HOMO of a material of the electron transport layer is 1.0 eV or more, and
a difference between a LUMO of the material of the hole transport layer and a LUMO of the material of the electron transport layer is 1.0 eV or more.

26-32. (canceled)
